(19) United States
(12) Patent Application Publication
(10) Pub. No.: US 2026/0003145 A1
(43) Pub. Date: Jan. 1, 2026

(54) PHOTONIC ENGINE WITH FACETS AND THE METHODS OF FORMING THE SAME

(71) Applicant: Taiwan Semiconductor Manufacturing Co., Ltd., Hsinchu (TW)

(72) Inventors: Zi-Jheng Liu, Taoyuan City (TW); Chiahung Liu, Hsinchu (TW); Ming-Fa Chen, Taichung City (TW)

(21) Appl. No.: 18/915,105

(22) Filed: Oct. 14, 2024

Related U.S. Application Data
(60) Provisional application No. 63/665,305, filed on Jun. 28, 2024.

(51) Int. Cl. G02B 6/43; H01L 23/31; H01L 23/48; H01L 25/16

(52) U.S. Cl. CPC G02B 6/43; H01L 23/3121; H01L 23/481; H01L 25/167

(57) ABSTRACT

A method includes forming a reconstructed wafer, which includes a supporting substrate, an electronic die over the supporting substrate, and a photonic die over the electronic die. The method further includes a first etching process to form a first trench in the reconstructed wafer, and a second etching process to form a second trench. The photonic die has a first sidewall facing the first trench. The second trench extends from a bottom of the first trench to the supporting substrate, and the second etching process results in a second sidewall facing the second trench. The method further includes forming a protection layer on the first sidewall and the second sidewall, and sawing the supporting substrate to form a photonic package comprising the photonic die, the electronic die, and a portion of the supporting substrate

### PRIORITY CLAIM AND CROSS-REFERENCE

This application claims the benefit of the following provisionally filed U.S. patent application: Application No. 63/665,305, filed on Jun. 28, 2024, and entitled “PACKAGE,” which application is hereby incorporated herein by reference.

### BACKGROUND

Electrical signaling and processing are one of techniques for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, the devices integrating optical components and electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-17 illustrate the views of intermediate stages in the formation of a photonic engine including a photonic die in accordance with some embodiments.

FIGS. 18-19 illustrate the views of photonic engines including photonic dies in accordance with some embodiments.

FIGS. 20A, 20B, 21A, 21B, 22A, 22B, 23A, 23B, 24A and 24B illustrate the top views and side views of photonic engines in accordance with some embodiments.

FIG. 25 illustrates a process flow for forming a photonic engine in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package (a photonic engine) including a photonic die and the method of forming the same are provided. In accordance with some embodiments of the present disclosure, in the formation of the package, a first etching process and a second etching process are performed, each forming a facet (sidewall) for the respective package. The second etching process may be performed in the trenches formed in the first etching process. By performed two etching processes, both of the first etching process and the second process may be performed with lower strength, and hence the sidewalls of the resulting package are smoother.

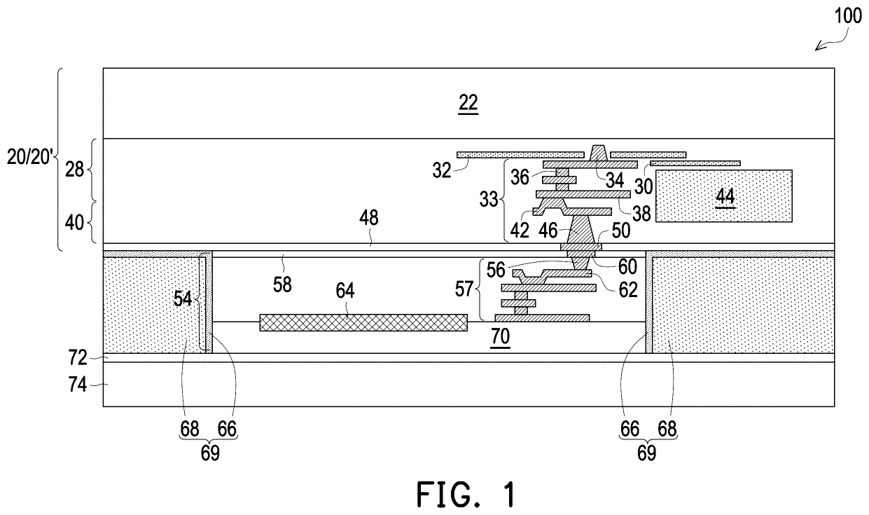

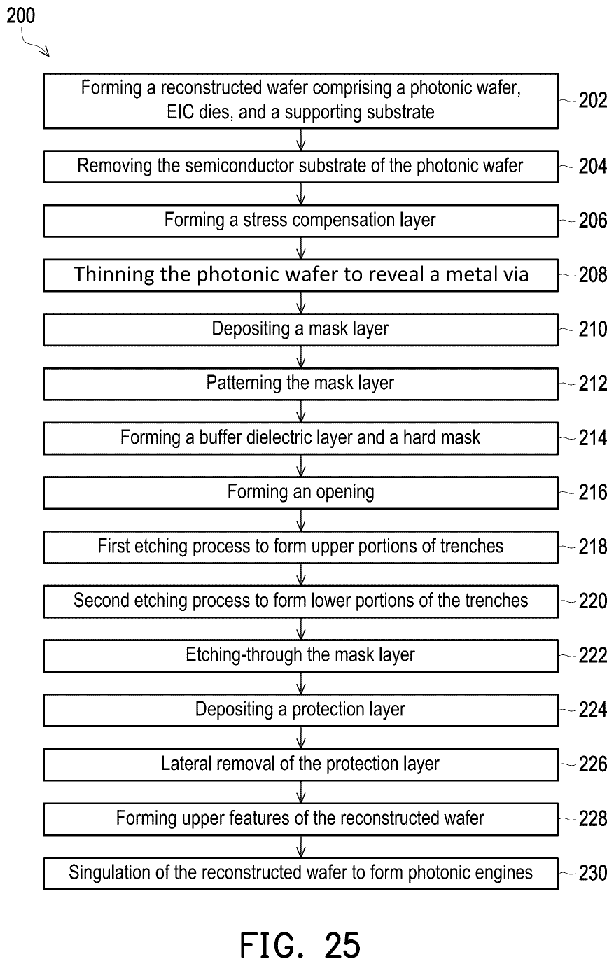

FIGS. 1 through 17 illustrate the cross-sectional views of intermediate stages in the formation of a photonic engine adopting edge coupling in accordance with some embodiments of the present disclosure. The corresponding processes are also reflected schematically in the process flow shown in FIG. 25.

Referring to FIG. 1, reconstructed wafer 100 is formed, which includes photonic wafer 20, electronic dies 54 and supporting substrate 74. The respective process is shown as process 202 in the process flow 200 as shown in FIG. 25. The brief process for forming reconstructed wafer 100 is discussed below.

Photonic wafer 20 is first formed. In accordance with some embodiments, photonic wafer 20 comprises a plurality of photonic dies 20′ that are identical to each other. Photonic dies 20′ may also be referred to as photonic Integrated circuit (PIC) dies.

Photonic die 20′ may include semiconductor substrate 22, which may be a silicon wafer in accordance with some embodiments. Photonic die 20′ may include photonic devices such as waveguides, grating couplers, modulators, and/or the like. In accordance with some embodiments, photonic die 20′ may include waveguides 30 and 32. Waveguide 30 may be a nitride waveguide, which may be formed of silicon nitride. Waveguide 32 may be a silicon waveguide. Silicon waveguide 32 may be formed by bonding a silicon layer to an overlying dielectric layer 28, followed by the patterning of the silicon layer through etching, so that waveguides, grating couplers, and the like are formed. In accordance with some embodiments, waveguide 30 is used for edge coupling, and is configured to receive optical signals from an optical fiber. The optical signal received by waveguide 30 may be coupled to silicon waveguide 32.

In accordance with some embodiments, dielectric layers 28 are formed on semiconductor substrate 22, in which the photonic devices such as waveguides 30 and 32 are formed. Dielectric layers 28 may comprise light-transparent and low-loss dielectric materials such as silicon oxide. Dielectric layers 28 may include a plurality of dielectric layers formed of different materials, which may include Inter-Metal Dielectric (IMDs) that may include a low-k dielectric material(s) such as porous silicon oxynitride. There may also be etch stop layers formed between the low-k dielectric materials. The etch stop layers may comprise AlN, AlO, SiON, or the like, or multi-layers thereof.

Interconnect structure 33 is formed, which may include vias 36 and metal lines 38 and the respective portions of dielectric layers 28. Vias 36 and metal lines 38 may be formed through single damascene processes and/or dual damascene processes. In accordance with some embodiments, metal via 34 is formed to connect to interconnect structure 33. Metal via 34 may be formed through a damascene process such as a single damascene process.

For example, via 34, vias 36, and metal lines 38 may be formed through a single damascene process by forming openings in dielectric layers 28, and filling the openings with conductive materials. The conductive materials may include a diffusion barrier layer formed of TiN, TaN, Ti, Ta, or the like, and a metallic material such as tungsten, copper, cobalt, or the like. A planarization process such as a CMP process or a mechanical grinding process may be performed to remove excess conductive material. The remaining portions of the diffusion barrier layer and the metallic material form vias 34 and 36 and metal lines 38.

A plurality of dielectric layers 40 are then formed. In accordance with some embodiments, some of the dielectric layers 40 may comprise inorganic dielectric materials such as silicon oxide, silicon nitride, silicon carbide, silicon oxynitride, or the like, which may form passivation layers. The corresponding dielectric layers may be formed through deposition processes, followed by a planarization process such as a Chemical Mechanical Polish (CMP) process or a mechanical grinding process. Some of dielectric layers 40 may be formed of or comprise an organic dielectric material(s), which may include a polymer(s) such as polyimide, polybenzoxazole (PBO), benzocyclobutene (BCB), or the like.

In accordance with some embodiments, metal pad(s) 42 are formed to electrically connect to interconnect structure 33. Metal pads 42 may be formed of or comprise aluminum copper, copper, nickel, or the like, or multi-layers thereof. In accordance with some embodiments, the formation of metal pads 42 may comprise depositing one of the passivation layers, forming openings in the corresponding passivation layer to expose the metal pads in interconnect structure 33, depositing a metal layer that extends into the openings, and performing an etching process to etch the metal layer. The remaining portions of the metal layer form metal pads 42.

In accordance with some embodiments, bulk dielectric region 44 is formed under waveguide 30. In accordance with some embodiments, bulk dielectric region 44 is a large dielectric block formed of a homogenous dielectric material. The bulk dielectric region 44 is close to and overlapped by waveguide 30. The bulk dielectric region 44 is used to form a homogenous environment, so that the interference from the surrounding environment to waveguide 30 is reduced. In accordance with some embodiments, bulk dielectric region 44 is formed of or comprise silicon oxide, silicon oxynitride, silicon carbide, silicon oxycarbide, or the like, or other dielectric materials.

Conductive feature 46 such as a metal via is formed to electrically connect to the metal pad 42 and metal lines 38. Bond layer 48 is formed. In accordance with some embodiments, bond layer 48 may have a multi-layer structure or a single layer structure. Bond layer 48 may comprise a silicon-containing dielectric material such as silicon oxide, silicon nitride, silicon carbide, silicon oxynitride, silicon oxycarbide, silicon oxycarbonitride or the like.

Bond pads 50 are formed in bond layer 48. In accordance with some embodiments, bond pads 50 may comprise copper, and may comprise a diffusion barrier, such as Ti, TiN, Ta, TaN, or the like. The formation process may include etching bond layer 48 to form openings, depositing a conductive material to fill the openings, and performing a planarization process to remove the portions of the conductive material over bond layer 48.

Further referring to FIG. 1, device die 54, which may be an Electronic Integrated circuit (EIC) die (also referred to as an electronic die) or another type of die such as an independent passive device die, an Integrated Voltage Regulator (IVR) die, or the like is bonded to the photonic die 20′. Throughout the description, die 54 is referred to as n EIC die 54.

In accordance with some embodiments, EIC die 54 includes a semiconductor substrate 70 (which may be a silicon substrate) and the integrated devices 64 formed on a surface of semiconductor substrate 70. The integrated circuit devices 64 (which may include active devices such as transistors) are used to support the functionality of the photonic die in accordance with some embodiments. The integrated circuit devices 64 may also include passive devices such as capacitors, resistors, or the like. Interconnect structure 57 is formed in EIC die 54, and to electrically connect to the integrated circuit devices 64.

In accordance with some embodiments, integrated circuit devices 64 may include the integrated circuits for communicating with the photonic die 20′, such as the circuits for controlling the operation of the photonic die 20′. For example, the EIC die 54 may include controllers, drivers, amplifiers, and the like, and combinations thereof, the EIC die 54 may also include a Central Processing Unit (CPU). In accordance with some embodiments, the EIC die 54 includes the circuits for processing the electrical signals converted from the optical signals received from the photonic die 20′, and/or the electrical signals to be converted to the optical signals that will be transmitted out of the photonic die 20′. The EIC die 54 may also control high-frequency signaling of the photonic die 20′ according to electrical signals (digital or analog) received from another device or die, in accordance with some embodiments. In accordance with some embodiments, the EIC die 54 may include a circuit that provides Serializer/Deserializer (SerDes) functionality. In this manner, the EIC may act as a part of an I/O interface between optical signals and electrical signals.

EIC die 54 may include metal pad 62, via 56 connected to metal pad 62, and bond pad 60 electrically connected to via 56. The bond pad 60 may be electrically connected to the integrated circuits in EIC die 54.

The bonding between the photonic die 20′ and the EIC die 54 may include metal-to-metal direct bonding, solder bonding, or hybrid bonding that includes both of metal-to-metal direct bonding and fusion bonding. For example, the bond layer 58 is bonded to bond layer 48 through fusion bonding. The material of bond layer 58 may be the same or different from the material of bond layer 48.

It is appreciated that the structure as illustrated in FIG. 1 is at wafer level, wherein a plurality of identical EIC dies 54 may be bonded to a plurality of photonic dies 20′ of photonic wafer 20 in accordance with some embodiments. A gap-fill process is performed in accordance with some embodiments, wherein the gaps between EIC dies 54 are filled to form dielectric regions (that encircle the EIC dies 54), which are also referred to as gap-fill regions.

Further referring to FIG. 1, after the bonding of EIC dies 54 to photonic dies 20′, dielectric barrier 66 is deposited. The deposition process includes a conformal deposition process such as Atomic Layer Deposition (ALD), Chemical Vapor Deposition (CVD), or the like. The material of dielectric barrier 66 is selected to have good adhesion ability on EIC dies 54. In accordance with some embodiments, dielectric barrier 66 is formed of or comprise silicon nitride, silicon carbo-nitride, silicon oxynitride, silicon carbide, or the like, which material may be different from the material of dielectric region 68.

Dielectric region 68 is then formed. In accordance with some embodiments, the formation process may include depositing a dielectric material, and performing a planarization process such as a CMP process or a mechanical grinding process on the deposited dielectric material. The planarization process may use semiconductor substrate 70 as a CMP stop layer. The dielectric material of dielectric region 68 may comprise silicon oxide, silicon oxynitride, or the like. Dielectric barrier 66 and dielectric region 68 are collectively referred to as gap-fill regions 69.

A bond layer (an upper portion of the illustrated bond layer 72) is then formed on semiconductor substrate 70 and gap-fill regions 69, for example, through a deposition process. In accordance with some embodiments, the bond layer is formed of or comprise silicon oxide, silicon nitride, silicon carbide, silicon oxynitride, silicon oxycarbide, silicon oxycarbonitride, or the like.

Supporting substrate 74 (which may be a wafer) is bonded to bond layer 72. In accordance with some embodiments, supporting substrate 74 comprises a silicon substrate (a silicon wafer). There may be another bond layer pre-formed on supporting substrate 74 before the bonding, and the bond layer formed on the EIC dies 54 and gap-fill regions 69 is bonded to the bond layer pre-formed on semiconductor substrate 74 to form bond layer 72. The bonding may include fusion bonding.

Throughout the description, the structure shown in FIG. 1 is referred to as a reconstructed wafer 100. In subsequent processes as shown in FIGS. 1 through 15, further processes are performed on the reconstructed wafer 100 to form more features.

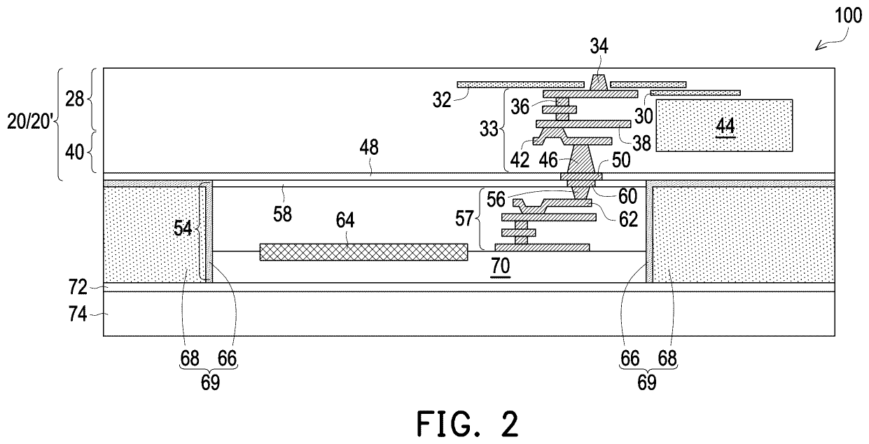

The semiconductor substrate 22 of photonic wafer 20 is then removed, and the resulting structure is shown as shown in FIG. 2. The respective process is shown as process 204 in the process flow 200 as shown in FIG. 25. In accordance with some embodiments, the removal of semiconductor substrate 22 may comprise a CMP process, a mechanical grinding process, or the like. A dielectric layer 28 is thus exposed. In accordance with alternative embodiments in which photonic die 20′ include active devices, the semiconductor substrate 22 may remain.

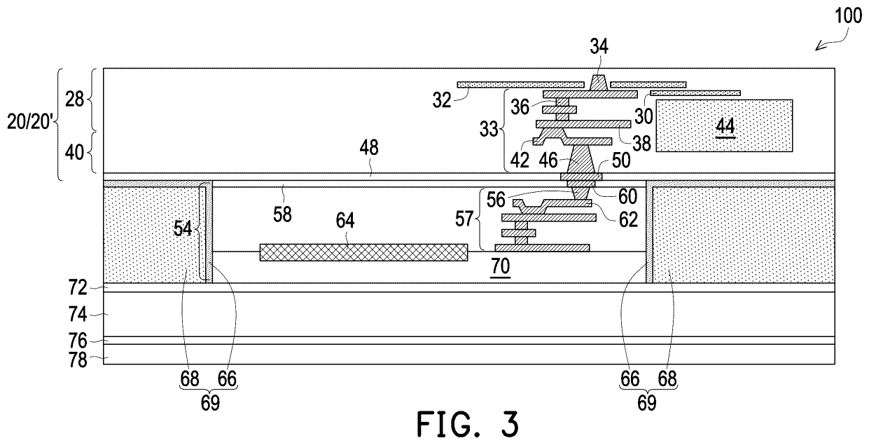

Referring to FIG. 3, stress compensation layer 78 is deposited on supporting substrate 74. The respective process is shown as process 206 in the process flow 200 as shown in FIG. 25. In accordance with some embodiments, dielectric buffer layer 76 is deposited on semiconductor substrate 74 first. Dielectric buffer layer 76 may comprise silicon oxide or other materials. Stress compensation layer 78 is deposited on dielectric buffer layer 76. Stress compensation layer 78 has an internal stress, and is used to apply a stress to the overlying structure, so that the warpage of the resulting reconstructed wafer 100 is reduced. In accordance with some embodiments, stress compensation layer 78 comprises silicon nitride. The stress in stress compensation layer 78 may be adjusted by adjusting the process condition of the deposition process. The thickness of stress compensation layer 78 may be in the range between about 1,000 Å and about 6,000 Å.

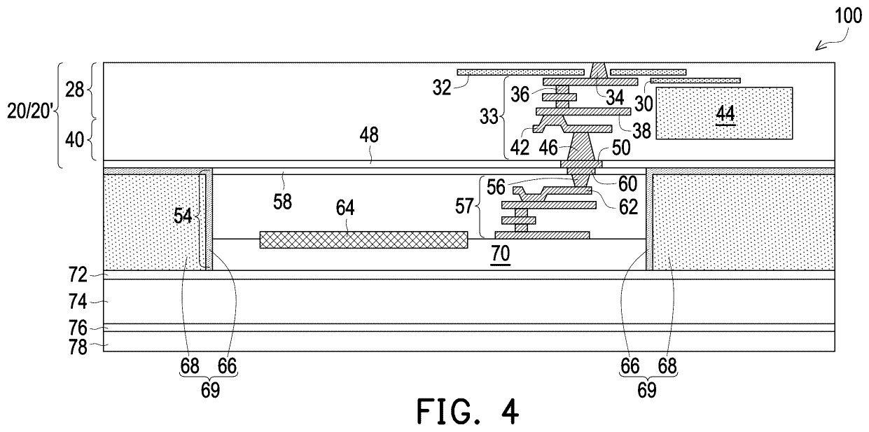

FIG. 4 illustrates a thinning process of the dielectric layer 28 of photonic wafer 20, so that metal via 34 is exposed. The respective process is shown as process 208 in the process flow 200 as shown in FIG. 25. The thinning process may be performed through a CMP process or a mechanical grinding process.

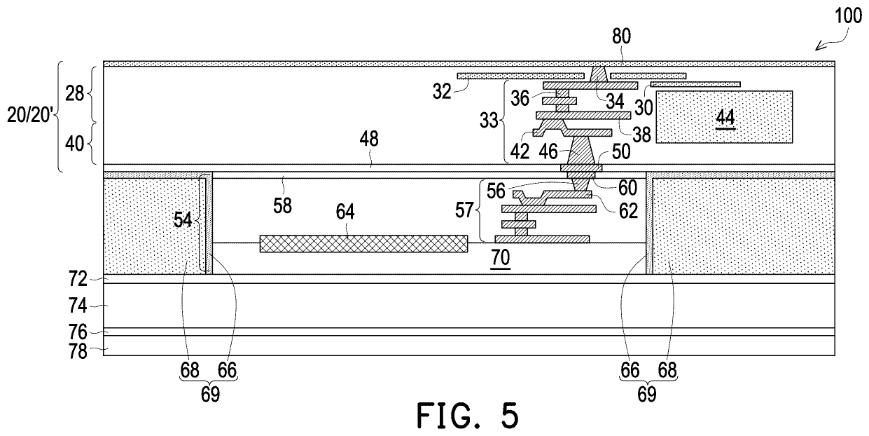

FIG. 5 illustrates the deposition of mask layer 80. The respective process is shown as process 210 in the process flow 200 as shown in FIG. 25. The formation process may include a deposition process. In accordance with some embodiments, mask layer 80 is formed of or comprises silicon nitride, silicon carbide, or the like.

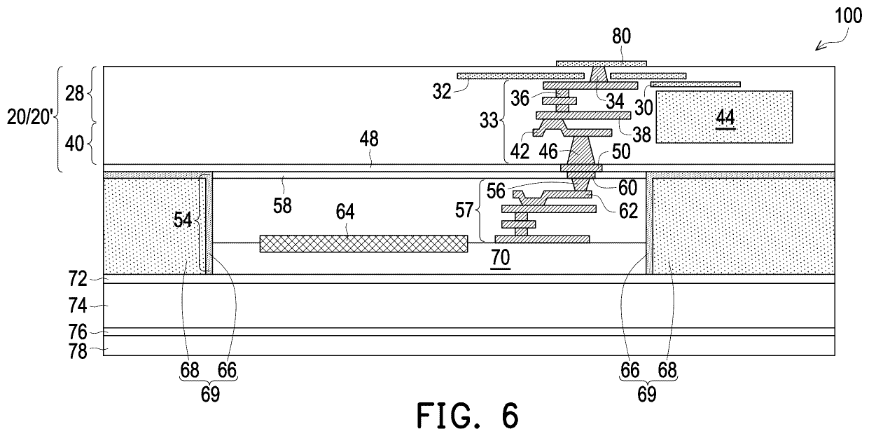

Next, as shown in FIG. 6, an etching process is performed to pattern mask layer 80, with a portion of mask layer 80 being left covering metal via 34 to act as an etch stop layer for subsequent processes. The respective process is shown as process 212 in the process flow 200 as shown in FIG. 25.

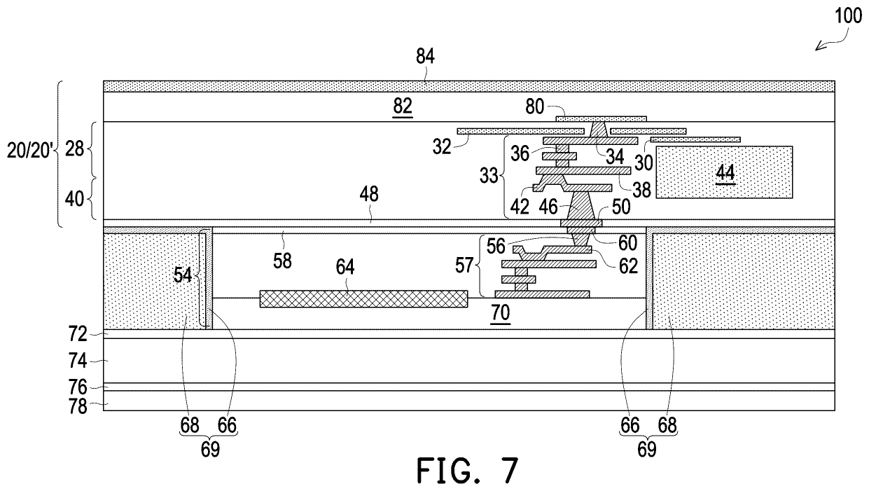

FIG. 7 illustrates the formation of buffer dielectric layer 82 and hard mask 84, which are formed through deposition processes. The respective process is shown as process 214 in the process flow 200 as shown in FIG. 25. In accordance with some embodiments, buffer dielectric layer 82 comprises silicon oxide, and hard mask 84 comprises silicon nitride, while other dielectric materials may also be used.

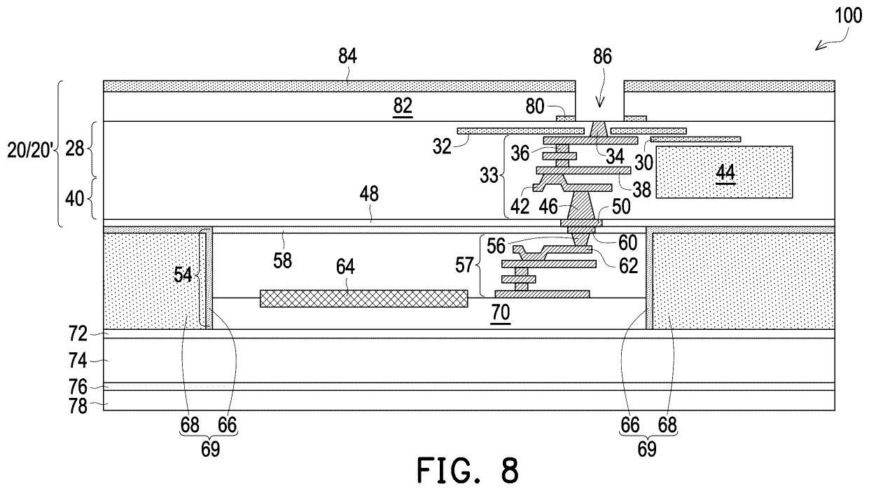

Referring to FIG. 8, hard mask 84 and buffer dielectric layer 82 are etched to form opening 86. The respective process is shown as process 216 in the process flow 200 as shown in FIG. 25. The etching may be stopped on mask layer 80, so that in subsequent processes, mask layer 80 may protect the underlying metal via 34 from being damaged and oxidized.

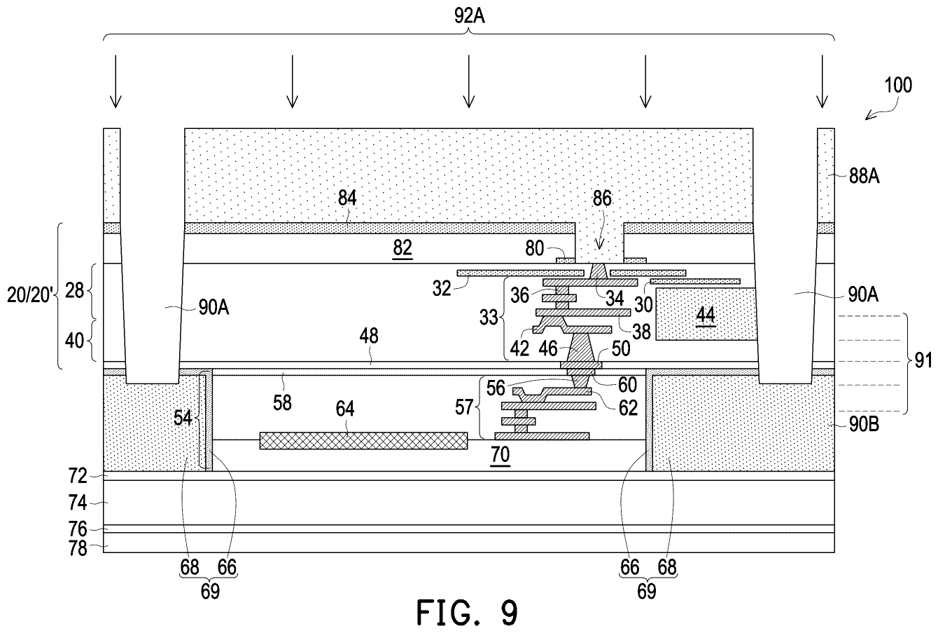

FIG. 9 illustrates a first etching process of a two-photo-two-etching (2P2E) process in order to groove reconstructed wafer 100. The respective process is shown as process 218 in the process flow 200 as shown in FIG. 25. In accordance with some embodiments, etching mask 88A is formed and patterned. Etching mask 88A may comprise a photoresist. An etching process 92A is then performed to form trenches 90A in the reconstructed wafer 100. When viewed in a top view of the reconstructed wafer 100, trenches 90A may be formed to have a grid pattern including a plurality trenches having lengthwise directions in a first direction, and a plurality of trenches having lengthwise directions in a second direction perpendicular to the first direction. Trenches 90A are formed in the scribe lines of the respective reconstructed wafer 100, which scribe lines are used for the subsequent sawing processes. After the first etching process 92, the etching mask 88A is removed.

As shown in FIG. 9, the bottoms of trenches 90A are at a top surface of EIC die 54, with trenches 90A extending into dielectric regions 68. In accordance with alternative embodiments, the bottoms of trenches 90A may be at a higher level such as lower than the bottom of bulk dielectric region 44 but higher than gap-fill regions 69. In accordance with yet alternative embodiments, the bottoms of trenches 90A may be at an intermediate level between a top surface and a bottom surface of bulk dielectric region 44. The corresponding levels of the possible positions of trenches 90A are shown using dashed lines 91.

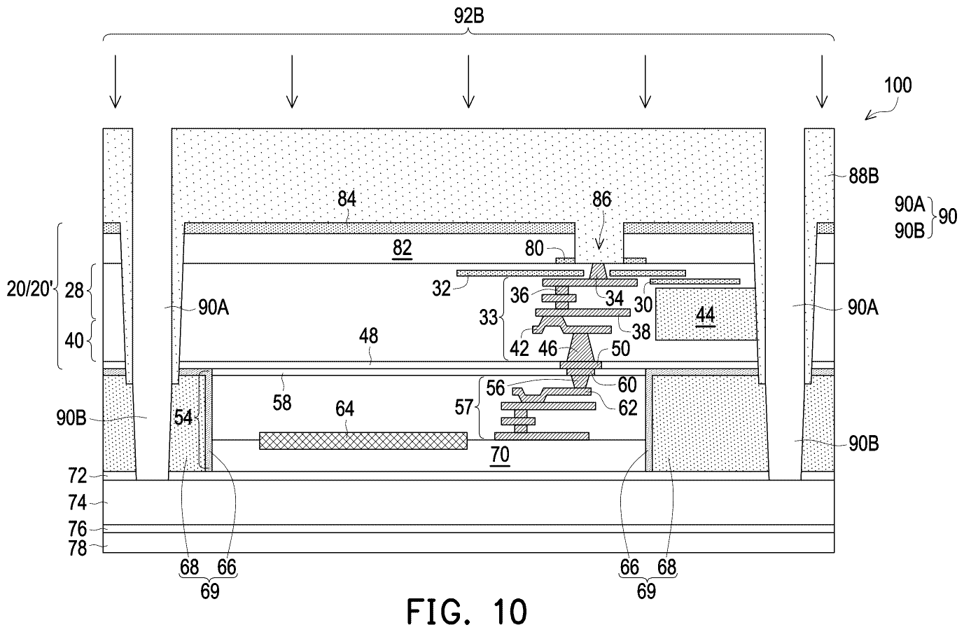

FIG. 10 illustrates a second etching process of the 2P2E process in order to groove reconstructed wafer 100. The respective process is shown as process 220 in the process flow 200 as shown in FIG. 25. In accordance with some embodiments, etching mask 88B is formed and patterned. Etching mask 88B may comprise a photoresist. The opening in etching mask 88B is narrower than trenches 90A. Accordingly, some portions of etching mask 88B are filled into trenches 90A. An etching process 92B is then performed to form trenches 90B in the reconstructed wafer 100. When viewed in a top view of the reconstructed wafer 100, trenches 90B may also be formed to have a grid pattern.

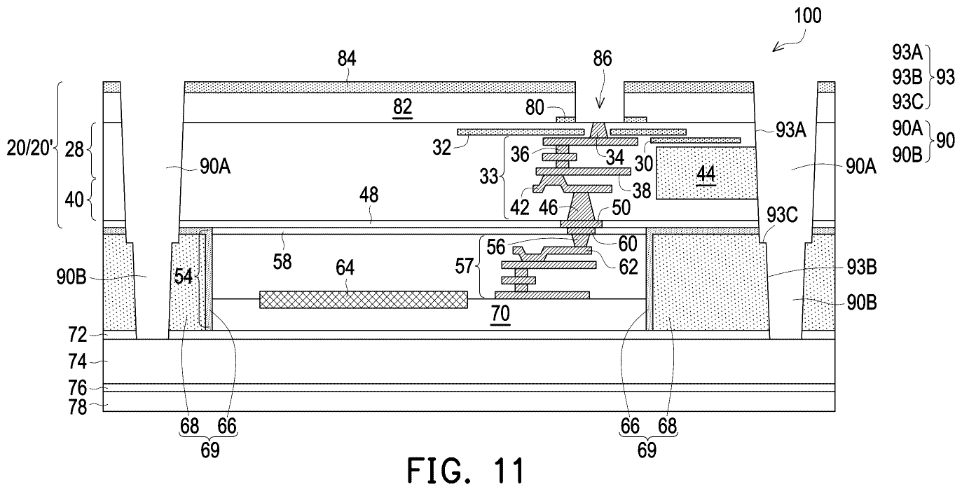

In accordance with some embodiments, trenches 90B penetrate through dielectric regions 68, and may stop on supporting substrate 74 or bond layer 72. After the etching process 92B, etching mask 88B is removed, for example, through an ashing process. Trenches 90A and 90B may be collectively referred to as trenches 90. The resulting trenches 90 are shown in FIG. 11.

As shown in FIG. 11, the reconstructed wafer 100 include surfaces 93, which include sidewalls (also referred to as facets) 93A and 93B, and the transition top surface 93C connecting the sidewalls 93A to the respectively underlying sidewalls 93B. The sidewalls 93A and transition top surfaces 93C are formed by the first etching process, and sidewalls 93B are formed by the second etching process.

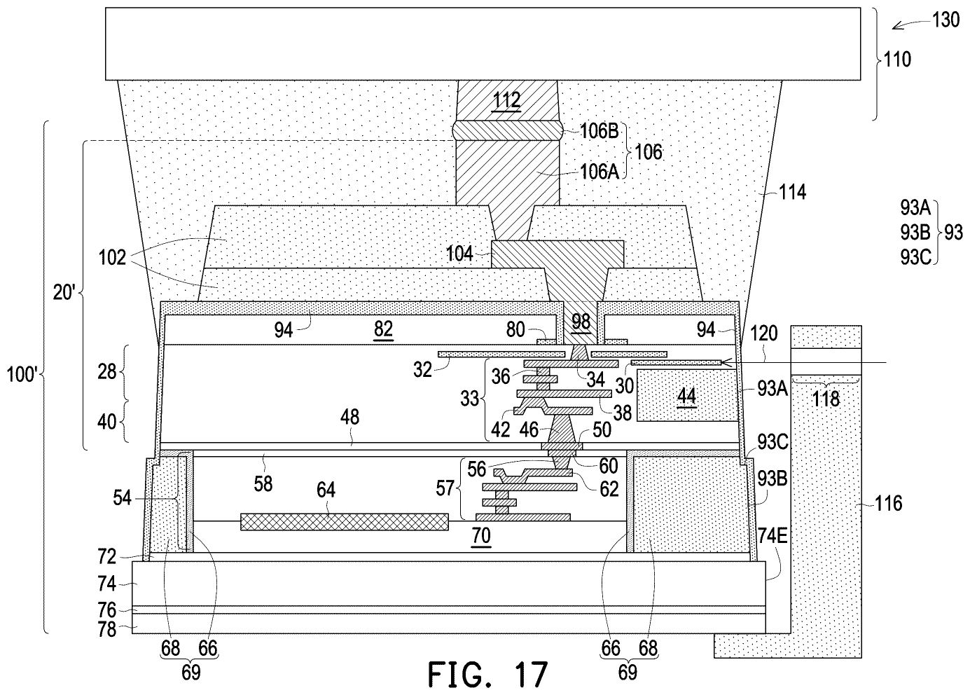

It is appreciated that by forming the trenches 90 through two etching processes, the first etching process, during which the sidewalls 93A are formed may have a reduced duration. When the resulting photonic package is used, as shown in FIG. 17, the optical signal will pass through the sidewall 93A to reach waveguide 30. Accordingly, the smoothness of sidewall 93A affects the scattering of the optical signal, and a smoother sidewall 93 results in less scattering, and lower loss in the optical signal.

Since the longer the etching duration is, the rougher the sidewalls 93A will be, by forming trenches 90 through two etching processes rather than one etching process, the first etching process may be performed in a shorter time. Accordingly, adopting two etching processes results in sidewalls 93A to be smoother.

In a subsequent process, an etching process is performed to remove the exposed portion of mask layer 80. The respective process is shown as process 222 in the process flow 200 as shown in FIG. 25. Metal via 34 is thus exposed.

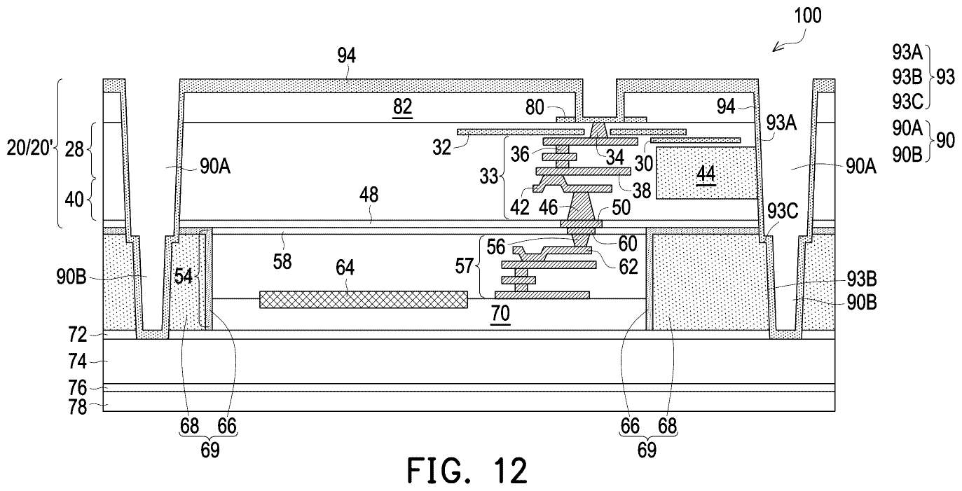

Referring to FIG. 12, protection layer 94 is formed. The respective process is shown as process 224 in the process flow 200 as shown in FIG. 25. In accordance with some embodiments, protection layer 94 comprises a same material as that of hard mask 84 (FIG. 11) such as silicon nitride, silicon oxynitride, silicon carbide, or the like. Accordingly, the hard mask 84 is shown as being a part of the protection layer 94, and is no longer illustrated. In accordance with alternative embodiments, hard mask 84 may be distinguishable from protection layer 94. In accordance with some embodiments, protection layer 94 is deposited using a conformal deposition process such as ALD, CVD, or the like.

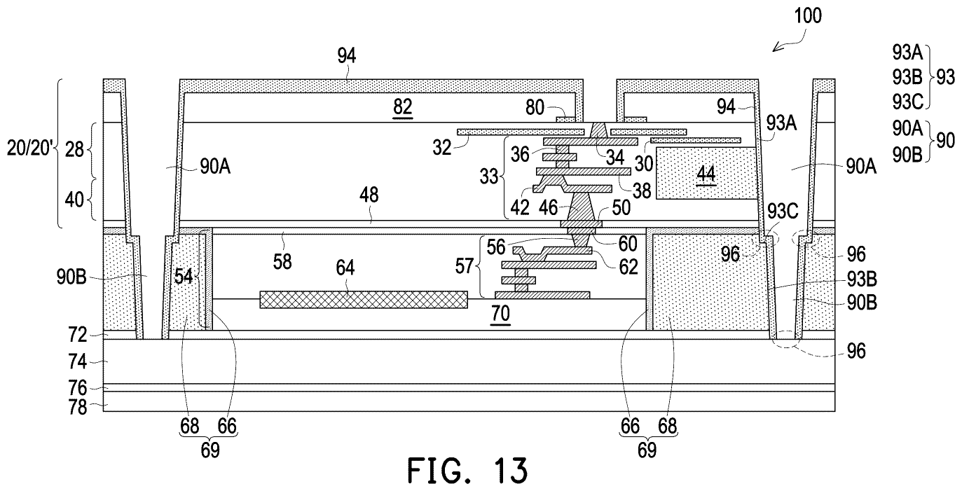

FIG. 13 illustrates the lateral removal process for removing the lateral portions of protection layer 94, for example, through an anisotropic etching process. The respective process is shown as process 226 in the process flow 200 as shown in FIG. 25. In accordance with some embodiments, the lateral portions of protection layer 94 at the bottom of trenches 90B may be fully removed, or may be thinned. Furthermore, the lateral portions of protection layer 94 on transition top surface 93C may be removed or thinned. Regions 96 are illustrated to show where protection layer 94 may be either fully removed, or thinned but not fully removed.

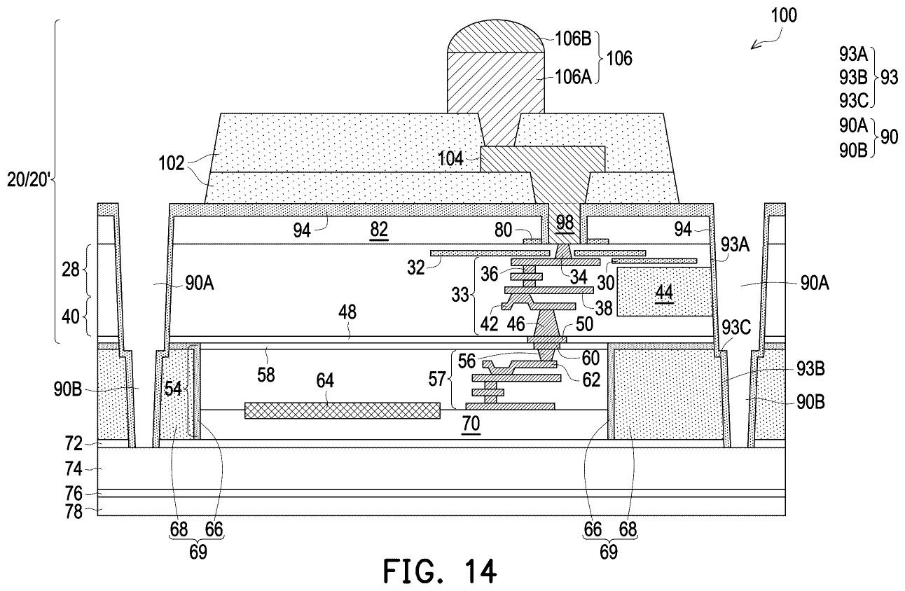

FIG. 14 illustrates the formation of upper features of the reconstructed wafer 110. The respective process is shown as process 228 in the process flow 200 as shown in FIG. 25. Dielectric layers 102 are formed over protection layer 94. In accordance with some embodiments, dielectric layers 102 may be formed of or comprises organic materials such as polymers. For example, dielectric layers 102 may be formed of or comprise polyimide, PBO, or the like.

Conductive features such as metal via 98, RDLs 104 and electrical connectors 106 are formed to electrically connect to metal vias 34 and the underlying interconnect structure, and to integrated circuit devices 64. In accordance with some embodiments, electrical connectors 106 include metal pillars 106A and solder regions 106B.

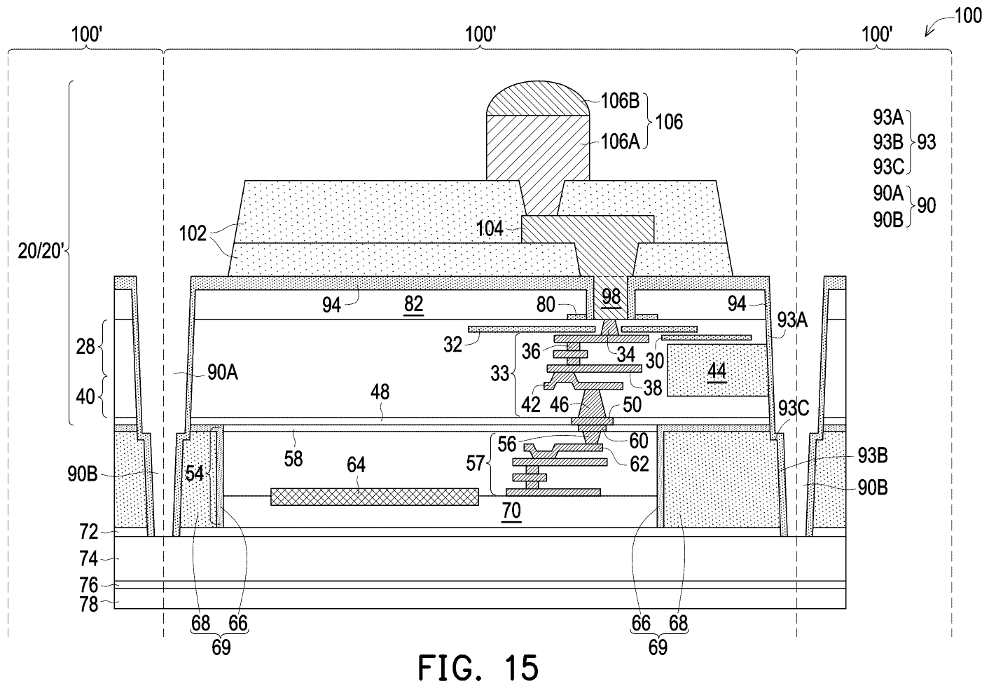

Subsequently, as shown in FIG. 15, a sawing process (also referred to as a singulation process) is performed to saw reconstructed wafer 100 and to form a plurality of photonic engines 100′. The respective process is shown as process 230 in the process flow 200 as shown in FIG. 25. The plurality of photonic engines 100′ are identical, and each may include a PIC die 20′, an EIC die 54, and a supporting substrate 74, which is sawed from the wafer-level supporting substrate 74.

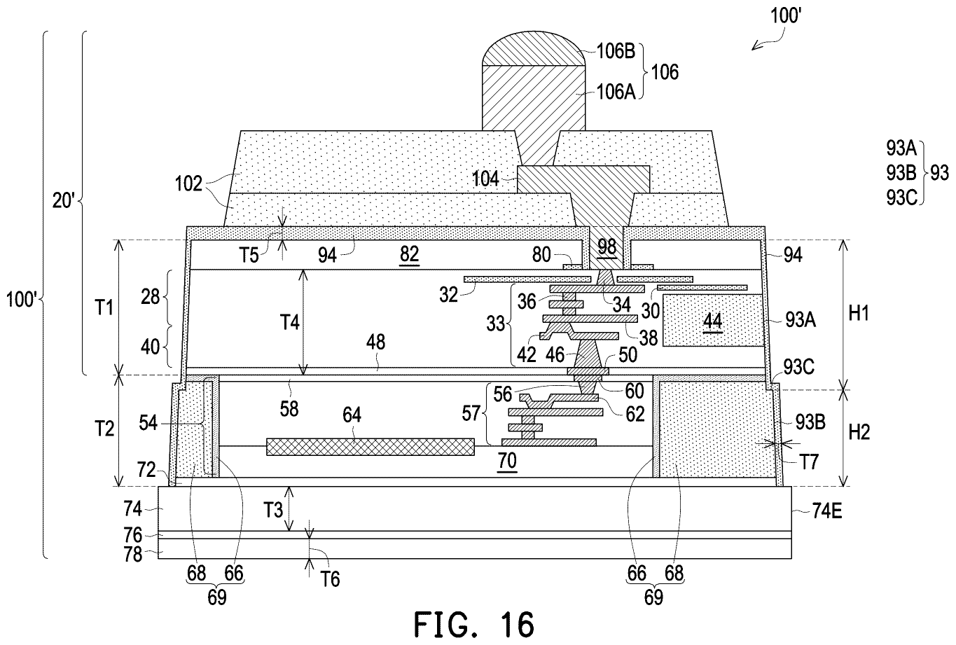

In accordance with some embodiments, the kerves of the sawing process pass through trenches 90. The surfaces 93 and the protection layer 94 thereon are not damaged. FIG. 16 illustrates one of the photonic engines 100′ in accordance with some embodiments. Due to the sawing of supporting substrate 74, edges 74E (FIG. 16) are formed. Supporting substrate 74 extends laterally beyond sidewalls 93A and 93B.

FIG. 17 illustrates the usage of photonic engine 100′ in accordance with some embodiments. Photonic engine 100′ may be bonded to a package component 110 that is connected to photonic engine 100′ through conductive feature 112, solder region 106B, and metal pillar 106A in accordance with some embodiments. Package 130 is thus formed. The package component 110 may include an interposer, a package substrate, a printed circuit board, or the like. Underfill 114 is dispensed into the gap between photonic engine 100′ and package component 110.

A Fiber Assembly Unit (FAU) 116 may be attached to the photonic engine 100′. An optical fiber 118 is aligned to waveguide 30 through edge coupling. A laser beam 120 may be projected out of optical fiber 118, and projected into waveguide 30. The laser beam 120 passes through sidewall 93A to reach waveguide 30, which may optically couple the optical signals into waveguide 32. The optical signals carried by the laser beam 120 are processed by photonic die 20′ and EIC die 54. The optical signals may alternatively be converted to electrical signal by the photonic die 20′, and the electrical signals are transferred to EIC die 54.

As shown in FIG. 17, optical signals pass through sidewall 93A. Since sidewall 93A is smoother due to that the first etching process 92A (FIG. 9) takes shorter time, the loss of the optical signal at sidewall 93A is reduced.

The ratio of height H1 of sidewall 93A and height H2 of sidewall 93B are adjusted to achieve good results. For example, if the value of height H1 (FIG. 16) is too big, the first etching process is too long, and the sidewall 93A will be rougher. This defeats the purpose of adopting two etching processes. If the value of height H1 is too small, and the bottom of trenches 90A are higher than the level of waveguide 30, the optical signal will have to pass sidewall 93B rather than sidewall 93A. Since height H2 of sidewall 93B is big in these embodiments, the sidewall 93B is also rough. In accordance with some embodiments, the ratio of H1/H2 may be in the range between about 0.3 and about 1.3. Also, height H1 may be small than height H2.

Referring to FIG. 16 again, some example dimensions are illustrated. In accordance with some embodiments, as shown in FIG. 16, the thickness Ti of PIC die 20′ may be in the range between about 10 μm and about 20 μm. The thickness T2 of EIC die 54 may be in the range between about 12 μm and about 24 μm. The thickness T3 of supporting substrate 74 may be in the range between about 500 μm and about 1,000 μm.

The ratio of (T4+T2)/(T1+T2) may be greater than 0.7 and smaller than 1, wherein thickness T4 is the thickness of the portion of EIC 20′ lower than buffer dielectric layer 82. Also, the thickness ratio T7/T5 and thickness ratio T7/T6 may be in the range between 0.05 and about 0.5, wherein thicknesses T5, T6, and Ty are the thicknesses of protection layer 94, the stress compensation layer T6, and the sidewall portion of protection layer 94, respectively.

In the embodiments as shown in FIG. 17, the bottoms of trenches 90A and the transition top surfaces 93C are in EIC die 54, and may be lower than the illustrated top surfaces of dielectric regions 68. This has the advantageous feature of using dielectric barrier 66 as a moisture barrier layer. In the embodiments in which the protection layer 94 is removed from transition top surface 93C or too thin, the moisture penetrating into dielectric region 68 may be further blocked by dielectric barrier 66.

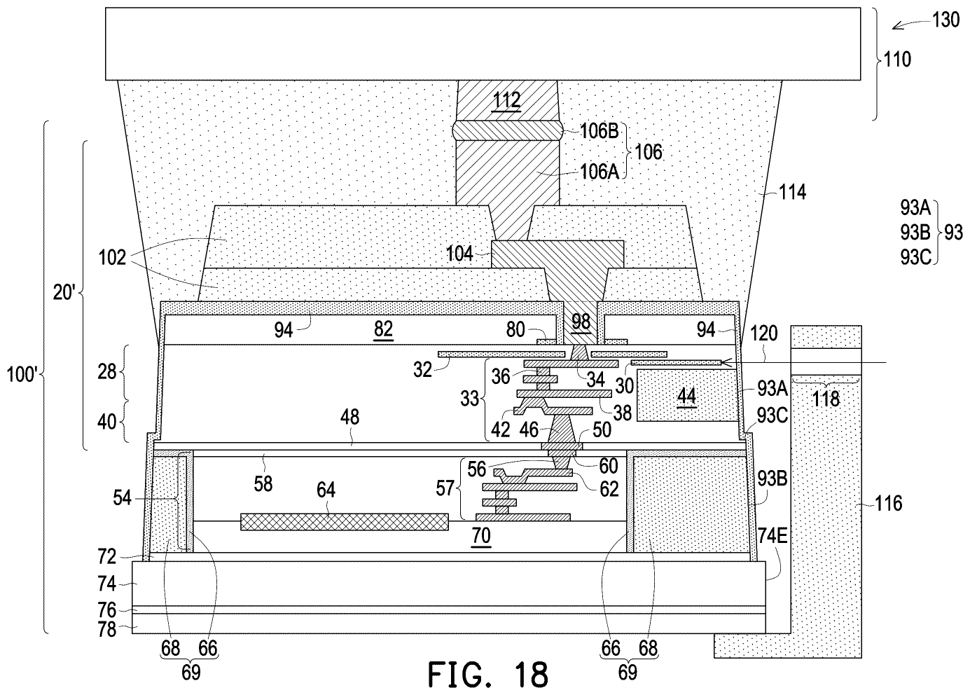

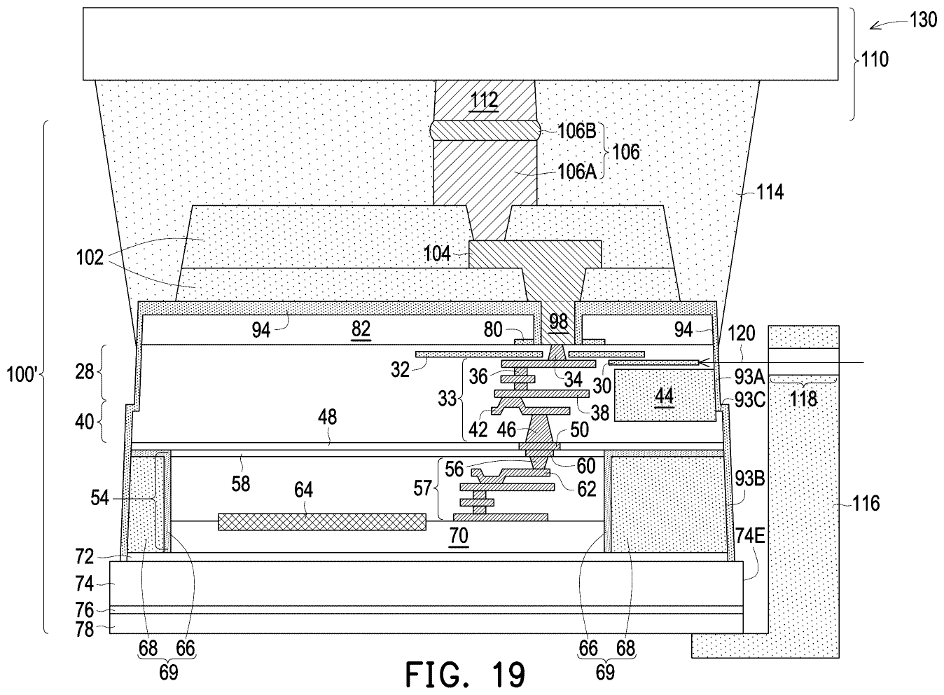

FIGS. 18 and 19 illustrate the packages 130 in accordance with alternative embodiments. These embodiments are similar to the embodiments as shown in FIGS. 1 through 12, except that the stopping point of the first etching process is different from that of the preceding embodiments. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

Referring to FIG. 18, the bottoms of trenches 90A and the transition top surfaces 93C are in PIC die 20′, and are lower than the bulk dielectric region 44. The transition top surfaces 93C are thus the surfaces of dielectric layers 40 and may be lower than the bulk dielectric region 44. Dielectric layers 40 may be dense and may comprise silicon oxide, silicon nitride, and polymer layers. These layers may act as a moisture barrier layer. In the embodiments in which the protection layer 94 is removed from transition top surface 93C or too thin, the moisture will be blocked by dielectric layers 40.

Referring to FIG. 19, the bottoms of trenches 90A and the transition top surfaces 93C are in PIC die 20′, and are at an intermediate level between the top surface and the bottom surface of the bulk dielectric region 44. The transition top surfaces 93C are thus the surfaces of bulk dielectric region 44. Since bulk dielectric region 44 may be wide, bulk dielectric region 44 may also help to block the diffusion of moisture, at least partially.

In each of the embodiments as shown in FIGS. 17-19, each of the sidewalls 93A and 93B may be vertical or slightly slanted. For example, when the vertical sidewalls are defined as having slant angles (formed between the sidewalls and horizontal planes) equal to 90 degrees, the slant angle of each of the sidewalls 93A and 93C may be in the range between about 85 degrees and about 90 degrees.

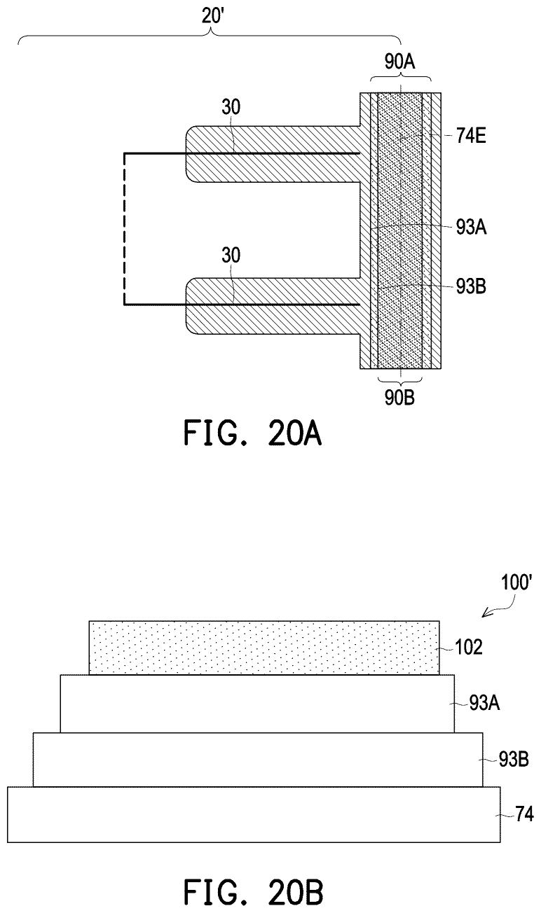

FIGS. 20A, 20B, 21A, 21B, 22A, 22B, 23A, 23B, 24A and 24B illustrate the top views and sidewalls of photonic engines in accordance with some embodiments. The figures whose figure numbers are followed by letter A are the top views of the structure, which may be viewed from the top of the structure shown in FIG. 15. Two waveguides 30 are illustrated, and the line in waveguide 30 illustrate where the optical paths. The positions of edges 74E of supporting substrate 74 (also refer to FIG. 15), at which the supporting substrate 74 is sawed, is illustrated.

In accordance with some embodiments, the optical signals are conducted into EIC die 20′, with the two illustrated waveguides 30 serving as two optical signal channels. In accordance with alternative embodiments, the two waveguides 30 are used to loop back optical signals. For example, the optical signal transmitted into the upper waveguide 30 may be looped back (through the optical path represented by the dashed line) out of PIC die 20′ through the lower waveguide 30. If the optical signal may be received from the lower waveguide 30, it indicates that optical fibers are correctly aligned to waveguides 30. Otherwise, if the optical signal cannot be received from the lower waveguide 30, it indicates that optical fibers are not properly aligned to waveguides 30.

The figures whose figure numbers are followed by letter B are the side views of the structure, which may be viewed from the right side of the structures shown in FIGS. 17-19 toward left. Accordingly, the sidewalls of supporting substrate 74, sidewalls 93A and 93C, and dielectric layers 102 can be viewed, and are illustrated schematically.

In the embodiments as shown in FIG. 20A, in the top view, sidewall 93A is straight, and sidewalls 93B is straight and parallel to sidewall 93A. FIG. 20B illustrates the side views of the structure shown in FIG. 20A.

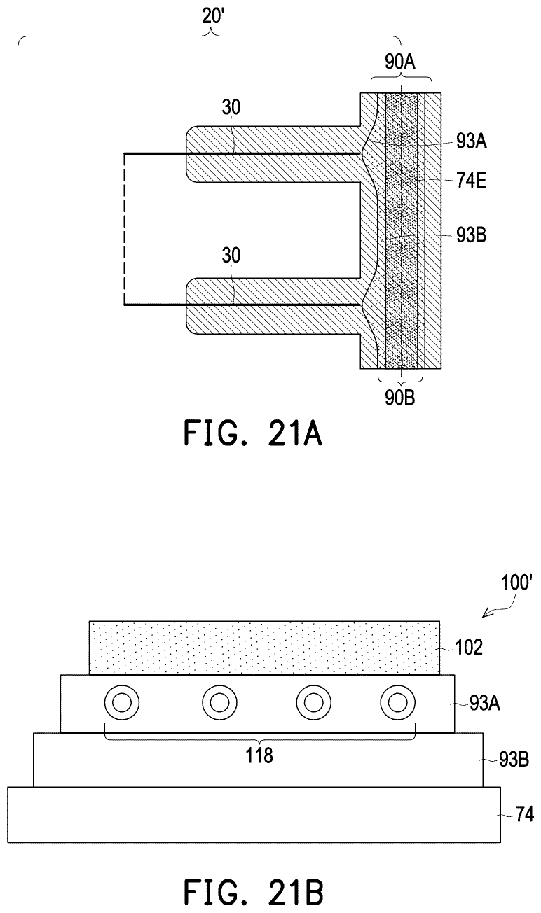

In the embodiments as shown in FIG. 21A, sidewall 20A is not straight, and may extend deeper into PIC die 20′ where it is aligned to waveguides 30. Sidewall 93B, on the other hand, is still straight in the top view. FIG. 21B illustrates the side view of the structure shown in FIG. 21A. FIG. 21B also illustrates optical fibers 118 in accordance with some embodiments.

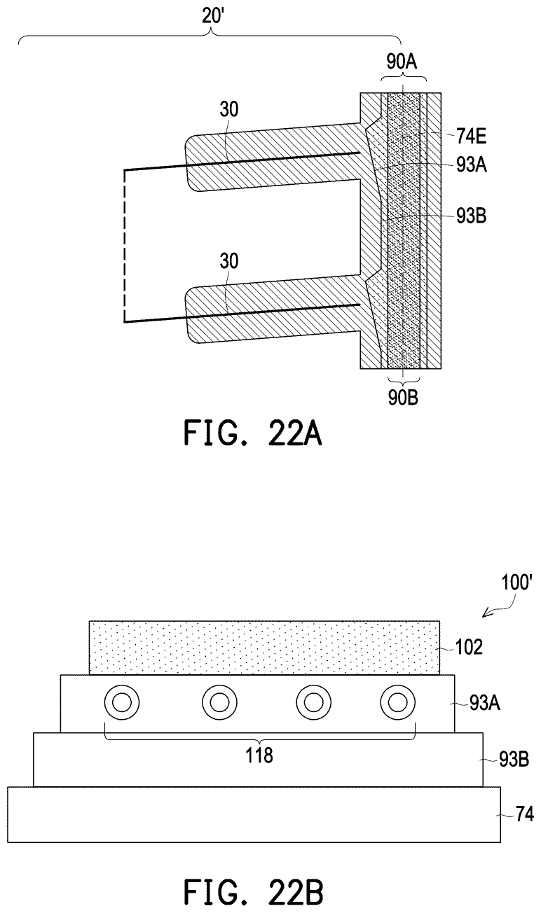

FIGS. 22A and 22B illustrate the top view and the side view, respectively of a photonic engine in accordance with alternative embodiments. These embodiments are similar to the embodiments shown in FIGS. 21A and 21B, except that portions of sidewall 93A have a non-symmetric pattern with relative to waveguides 30. In addition, waveguides 30 have lengthwise directions that are not perpendicular to the edge 74E of supporting substrate 74.

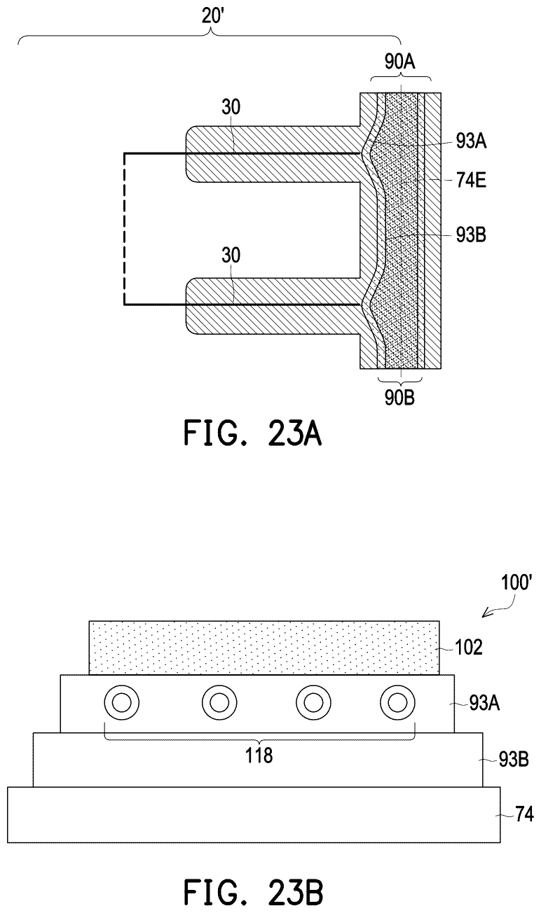

FIGS. 23A and 23B illustrate the top view and the side view, respectively of a photonic engine in accordance with alternative embodiments. These embodiments are similar to the embodiments shown in FIGS. 22A and 22B, except that waveguides 30 have lengthwise directions that are perpendicular to the edge 74E of supporting substrate 74. In addition, portions of sidewall 93A have a symmetric pattern with relative to waveguides 30.

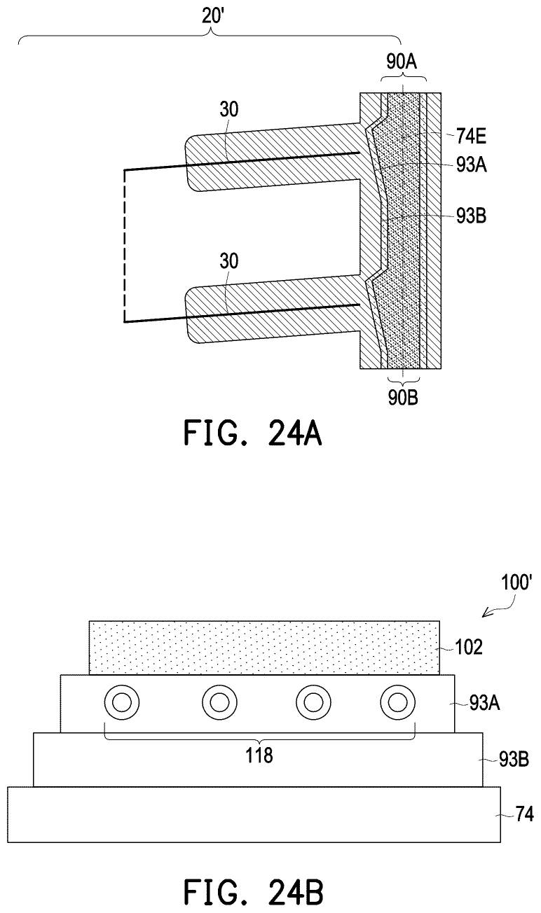

FIGS. 24A and 24B illustrate the top view and the side view, respectively of a photonic engine in accordance with alternative embodiments. These embodiments are similar to the embodiments shown in FIGS. 22A and 22B, except that portions of sidewall 93A have a non-symmetric pattern with relative to waveguides 30.

The embodiments of the present disclosure have some advantageous features. By performing 2P2E etching processes, the etching for forming the sidewalls of the EIC dies is controlled, so that the sidewalls of the EIC dies are smoother. The loss of the optical signal is thus reduced.

In accordance with some embodiments of the present disclosure, a method comprises forming a reconstructed wafer comprising a supporting substrate; an electronic die over the supporting substrate; and a photonic die over the electronic die; performing a first etching process to form a first trench in the reconstructed wafer, wherein the photonic die comprises a first sidewall facing the first trench; performing a second etching process to form a second trench, wherein the second trench extends from a bottom of the first trench to the supporting substrate, and wherein a second sidewall facing the second trench is generated by the second etching process; forming a protection layer on the first sidewall and the second sidewall; and sawing the supporting substrate to form a photonic package comprising the photonic die, the electronic die, and a portion of the supporting substrate.

In an embodiment, the photonic die comprises a waveguide, and wherein the waveguide is configured to receive an optical signal through edge coupling. In an embodiment, the photonic die is configured to convert the optical signal to an electronic signal. In an embodiment, the method further comprises aligning an optical fiber to the waveguide, wherein the optical fiber is configured to project a laser beam to the waveguide. In an embodiment, the first etching process is performed using a first etching mask, and the second etching process is performed using a second etching mask. In an embodiment, during the second etching process, the second etching mask comprises a portion in the first trench.

In an embodiment, a depth ratio of a first depth of the first trench to a second depth of the second trench is in a range between about 0.3 and about 1.3. In an embodiment, the first etching process stops when a bottom of the first trench is in the photonic die. In an embodiment, the first trench penetrates through a bulk dielectric region directly under the waveguide, and the first etching process is stopped when a bottom of the first trench is in the bulk dielectric region.

In an embodiment, the first trench penetrates through a bulk dielectric region directly under the waveguide, and the first etching process stops when a bottom of the first trench is lower than the bulk dielectric region. In an embodiment, the method further comprises performing a gap-filling process to form a gap-fill region aside of the electronic die, and wherein the first etching process stops when a bottom of the first trench is in the gap-fill region. In an embodiment, the first trench is shallower than the second trench.

In accordance with some embodiments of the present disclosure, a structure comprises a photonic package comprising a supporting substrate; an electronic die over and joined to the supporting substrate; a photonic die over the electronic die; a first sidewall comprising a first edge of the photonic die; a second sidewall lower than the first sidewall; and a transition top surface connecting the first sidewall to the second sidewall. In an embodiment, the structure further comprises a gap-fill region aside of the electronic die and underlying the photonic die, wherein the second sidewall comprises a second edge of the gap-fill region. In an embodiment, the transition top surface is a top surface of the gap-fill region.

In an embodiment, the photonic die comprises a waveguide configured to receive an optical signal through edge coupling when the optical signal passes through the first sidewall. In an embodiment, the photonic die comprises a bulk dielectric region, and wherein the transition top surface is a top surface of the bulk dielectric region. In an embodiment, the photonic die comprises a bulk dielectric region, and wherein the transition top surface is a top surface of the photonic die, and is lower than the bulk dielectric region.

In accordance with some embodiments of the present disclosure, a structure comprises a supporting substrate; an electronic die over and joined to the supporting substrate; a gap-fill region encircling the electronic die, wherein the gap-fill region comprises a first sidewall; a photonic die over the supporting substrate, wherein the photonic die comprises a second sidewall, and wherein a portion of the gap-fill region comprising a first part laterally beyond the second sidewall; and a protection layer on the first sidewall and the second sidewall. In an embodiment, the supporting substrate further comprises a third sidewall, and wherein a portion of the supporting substrate comprises a second part laterally beyond the first sidewall.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a reconstructed wafer comprising:
a supporting substrate;
an electronic die over the supporting substrate; and
a photonic die over the electronic die;
performing a first etching process to form a first trench in the reconstructed wafer, wherein the photonic die comprises a first sidewall facing the first trench;
performing a second etching process to form a second trench, wherein the second trench extends from a bottom of the first trench to the supporting substrate, and wherein a second sidewall facing the second trench is generated by the second etching process;
forming a protection layer on the first sidewall and the second sidewall; and
sawing the supporting substrate to form a photonic package comprising the photonic die, the electronic die, and a portion of the supporting substrate.

2. The method of claim 1, wherein the photonic die comprises a waveguide, and wherein the waveguide is configured to receive an optical signal through edge coupling.

3. The method of claim 2, wherein the photonic die is configured to convert the optical signal to an electronic signal.

4. The method of claim 2 further comprising aligning an optical fiber to the waveguide, wherein the optical fiber is configured to project a laser beam to the waveguide.

5. The method of claim 1, wherein the first etching process is performed using a first etching mask, and the second etching process is performed using a second etching mask.

6. The method of claim 5, wherein during the second etching process, the second etching mask comprises a portion in the first trench.

7. The method of claim 1, wherein a depth ratio of a first depth of the first trench to a second depth of the second trench is in a range between about 0.3 and about 1.3.

8. The method of claim 1, wherein the first etching process stops when a bottom of the first trench is in the photonic die.

9. The method of claim 8, wherein the first trench penetrates through a bulk dielectric region directly under a waveguide that is configured to receive an optical signal through edge coupling, and the first etching process is stopped when a bottom of the first trench is in the bulk dielectric region.

10. The method of claim 8, wherein the first trench penetrates through a bulk dielectric region directly under a waveguide that is configured to receive an optical signal through edge coupling, and the first etching process stops when a bottom of the first trench is lower than the bulk dielectric region.

11. The method of claim 1 further comprising performing a gap-filling process to form a gap-fill region aside of the electronic die, and wherein the first etching process stops when a bottom of the first trench is in the gap-fill region.

12. The method of claim 1, wherein the first trench is shallower than the second trench.

13. A structure comprising:
a photonic package comprising:
a supporting substrate;
an electronic die over and joined to the supporting substrate;
a photonic die over the electronic die;
a first sidewall comprising a first edge of the photonic die;
a second sidewall lower than the first sidewall; and
a transition top surface connecting the first sidewall to the second sidewall.

14. The structure of claim 13 further comprising a gap-fill region aside of the electronic die and underlying the photonic die, wherein the second sidewall comprises a second edge of the gap-fill region.

15. The structure of claim 14, wherein the transition top surface is a top surface of the gap-fill region.

16. The structure of claim 13, wherein the photonic die comprises a waveguide configured to receive an optical signal through edge coupling when the optical signal passes through the first sidewall.

17. The structure of claim 13, wherein the photonic die comprises a bulk dielectric region, and wherein the transition top surface is a top surface of the bulk dielectric region.

18. The structure of claim 13, wherein the photonic die comprises a bulk dielectric region, and wherein the transition top surface is a top surface of the photonic die, and is lower than the bulk dielectric region.

19. A structure comprising:
a supporting substrate;
an electronic die over and joined to the supporting substrate;
a gap-fill region encircling the electronic die, wherein the gap-fill region comprises a first sidewall;
a photonic die over the supporting substrate, wherein the photonic die comprises a second sidewall, and wherein a portion of the gap-fill region comprising a first part laterally beyond the second sidewall; and
a protection layer on the first sidewall and the second sidewall.

20. The structure of claim 19, wherein the supporting substrate further comprises a third sidewall, and wherein a portion of the supporting substrate comprises a second part laterally beyond the first sidewall.
